(19) United States
(12) Patent Application Publication
(10) Pub. No.: US 2015/0009639 A1
(43) Pub. Date: Jan. 8, 2015

(54) SYSTEM AND METHOD FOR HOUSING CIRCUIT BOARDS OF DIFFERENT PHYSICAL DIMENSIONS

(71) Applicants: Kimon Papakos, Evanston, IL (US); Mark E. Boduch, Geneva, IL (US)

(72) Inventors: Kimon Papakos, Evanston, IL (US); Mark E. Boduch, Geneva, IL (US)

(21) Appl. No.: 13/933,990

(22) Filed: Jul. 2, 2013

(51) Int. Cl. H05K 7/14; H05K 13/00

(52) U.S. Cl. CPC H05K 7/1427; H05K 13/00
USPC 361/752; 29/592.1; 312/223.1

(57) ABSTRACT

A system and corresponding method for housing circuit boards is provided. The circuit boards may differ in two physical dimensions. The circuit boards are placed in circuit board housings within an enclosure. Substantially planar positionable enclosure partitions of various lengths are strategically placed within the enclosure in order to form the circuit board housings. The positionable enclosure partitions provide a means to create circuit board housings that differ from one another in both a first dimension and a second dimension.

### RELATED APPLICATION

### None

### TECHNICAL FIELD OF THE INVENTION

The present invention relates generally to the housing of electronic and optical equipment and, more specifically, to a system and method for housing printed circuit board assemblies that differ in one or more physical dimensions.

### BACKGROUND

When new complex optoelectronic functions are first implemented, they are often implemented in the form of a large subassembly. These large subassemblies are then typically placed on printed circuit board assemblies (PCBAs) that are housed within an electronic enclosure along with other printed circuit board assemblies. Over time, as technology evolves, the large optoelectronic subassemblies are replaced with subassemblies of smaller and smaller physical size. As the optoelectronic subassemblies decrease in size, in order to save space within electronic enclosures, it is highly desirable to place the smaller subassemblies on printed circuit board assemblies of a smaller physical size. However, since existing electronic enclosures don't efficiently and easily provide a mechanism to accommodate printed circuit boards of various physical sizes, often space goes wasted in electronic enclosures as technologies evolve.

### SUMMARY

A system and corresponding method for housing circuit boards of different physical dimensions in accordance with an example embodiment of the present invention is provided.

An example embodiment is a system for housing circuit boards, comprising of an enclosure, one or more positionable enclosure partitions, and one or more circuit board housings (located within the enclosure). The circuit board housings are formed in part by the one or more enclosure partitions. Each of the circuit board housings has a first dimension and a second dimension—each of which may vary. The position of one or more enclosure partitions determines the value of one dimension of the circuit board housings, while the length of the partitions bound the value of a second dimension of the circuit board housings. A given system may contain multiple enclosure partitions. These partitions can be the same length, or they may be different lengths. Each enclosure partition may provide mechanical support for circuit boards placed inside the circuit board housings. The system may provide a number of locations within the enclosure where the partitions may be placed.

Embodiments also include a method of housing circuit boards. The method includes creating one or more circuit board housings within and enclosure by using one or more enclosure partitions. The method further includes choosing partitions of particular lengths in order to accommodate a range of values for a first dimension for one or more circuit board housings. In addition, the method may include positioning the partitions within the enclosure to accommodate a second dimension of one or more circuit board housings.

Further embodiments include an enclosure for housing circuit boards. The enclosure includes an interior cavity formed by connected top, bottom, rear, and side planar surfaces. In addition, the enclosure includes one or more enclosure partitions, whose length may vary. The enclosure partitions can be used to assist in forming circuit board housings for circuit boards. The position of the one or more partitions determine the value of one dimension of a given circuit board housing, while the length of one or more partitions bound the value of a second dimension of the circuit board housings.

Still further embodiments include a system that includes an enclosure with enclosure partitions, and multiple circuit boards. In such a system, circuit boards can be placed on either side of a given partition. The value of a first dimension of the circuit boards dictate the position of a given enclosure partition, while the value of a second dimension of the circuit boards on either side of the partition drives the length of the given partition.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1A is an illustration of a plurality of circuit boards of various physical sizes.

FIG. 1B is a three dimensional view of three circuit boards.

FIG. 1C is a three dimensional view of an enclosure used to house circuit boards.

FIG. 2A shows the front view of an enclosure configured to house eight circuit boards that are all a first circuit board width and a first circuit board height.

FIG. 2B shows the front view of an enclosure configured to house four circuit boards that are all a second circuit board width and a first circuit board height.

FIG. 2C shows the front view of an enclosure configured to house two circuit boards that are both a fourth circuit board width and a first circuit board height.

FIG. 2D shows the front view of an enclosure configured to house four circuit boards that are all a first circuit board width and a second circuit board height.

FIG. 2E shows the front view of an enclosure configured to house two circuit boards that are both a second circuit board width and a second circuit board height.

FIG. 2F shows the front view of an enclosure configured to house four circuit boards that are a first circuit board width and a first circuit board height, and two circuit boards that are a second circuit board width and a first circuit board height.

FIG. 2G shows the front view of an enclosure configured to house two circuit boards that are a first circuit board width and a first circuit board height, and a circuit board that is a second circuit board width and a first circuit board height, and a circuit board that is a fourth circuit board width and a first circuit board height.

FIG. 2H shows the front view of an enclosure configured to house two circuit boards that are a first circuit board width and a first circuit board height, and two circuit boards that are a second circuit board width and a first circuit board height, and a circuit board that is a first circuit board width and a second circuit board height.

FIG. 2I shows the front view of an enclosure configured to house two circuit boards that are a first circuit board width and a first circuit board height, and a circuit board that is a second circuit board width and a first circuit board height, and a circuit board that is a second circuit board width and a second circuit board height.

FIG. 2J shows the front view of an enclosure configured to house three circuit boards that are a first circuit board width and a first circuit board height, and a circuit board that is a second circuit board width and a first circuit board height, and a circuit board that has an irregular shape.

FIG. 3 shows the front view of an enclosure comprising of eight reconfigurable sub-cavities with a single non-configurable sub-cavity.

FIG. 4A shows the front view of the enclosure of FIG. 1C that illustrates the various interior and exterior surfaces of the enclosure.

FIG. 4B illustrates a system for housing circuit boards—comprising of an enclosure and two positionable enclosure partitions.

FIG. 4C illustrates another view of a system for housing circuit boards—comprising of an enclosure and two positionable enclosure partitions.

FIG. 4D shows the front view of the enclosure of FIG. 4C—configured to house six circuit boards.

FIG. 4E shows a detailed view of a slot on a positionable enclosure partition.

FIG. 4F shows a detail view of one possible attachment mechanism for a positionable enclosure partition.

FIG. 5A illustrates a system for housing circuit boards—comprising of an enclosure and both full-height and half-height positionable enclosure partitions, with a half-height positionable enclosure partition mounted from the top interior of the enclosure.

FIG. 5B shows the front view of the enclosure of FIG. 5A—configured to house five circuit boards.

FIG. 5C illustrates a system for housing circuit boards—comprising of an enclosure and both full-height and half-height positionable enclosure partitions, with a half-height positionable enclosure partition mounted from the bottom interior of the enclosure.

FIG. 5D shows the front view of the enclosure of FIG. 5C—configured to house five circuit boards.

FIG. 6 shows an alternative embodiment of both a full-height positionable enclosure partition and a half-height positionable enclosure partition.

### DETAILED DESCRIPTION

A description of example embodiments of the invention follows.

A printed circuit board (or PCB) is used to mechanically support and electrically interconnect electronic and optoelectronic components using conductive signal traces etched from copper sheets that are laminated onto a non-conductive substrate. Once a printed circuit board is populated with its electronic and optoelectronic components it is commonly referred to as a printed circuit board assembly (or PCBA). However, it is common within the industry to refer to printed circuit board assemblies as simply circuit boards, as is done in this patent application.

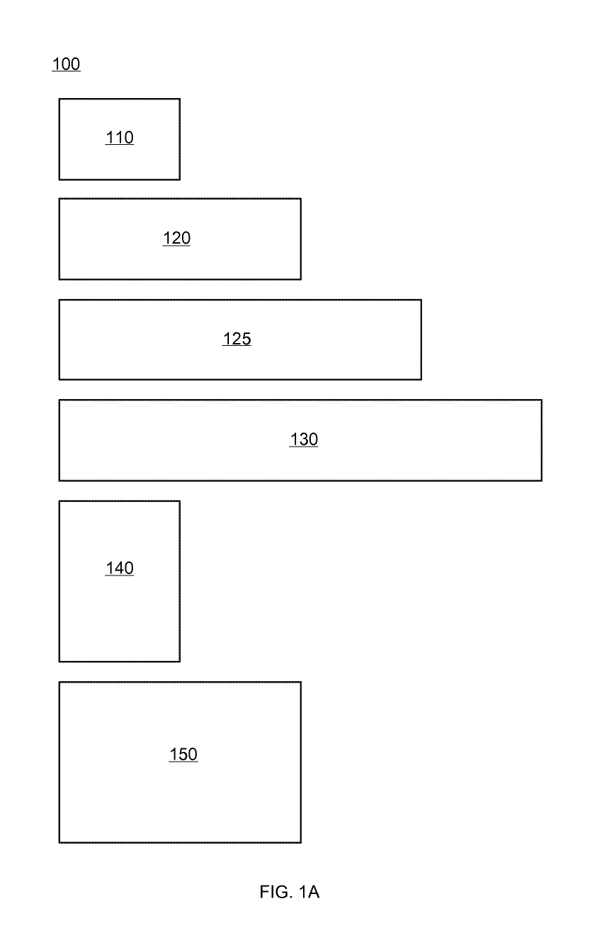

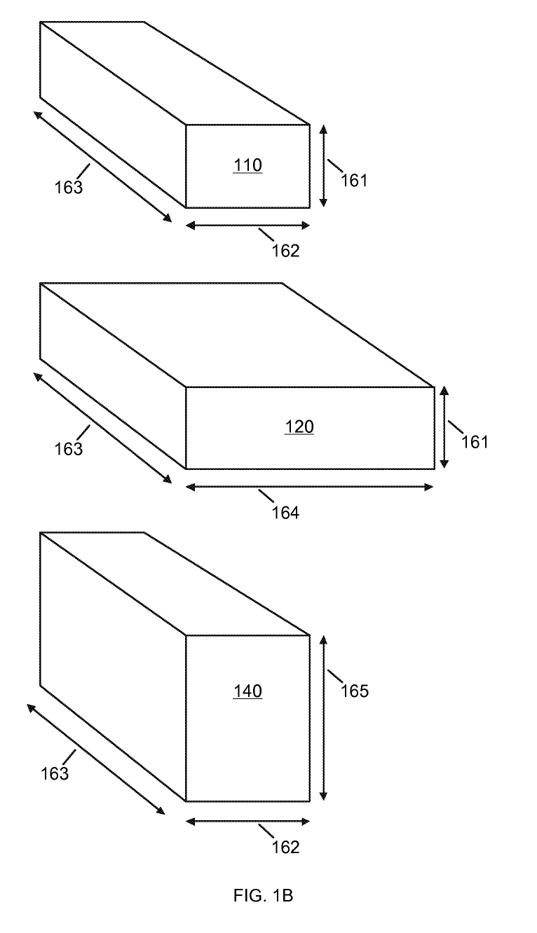

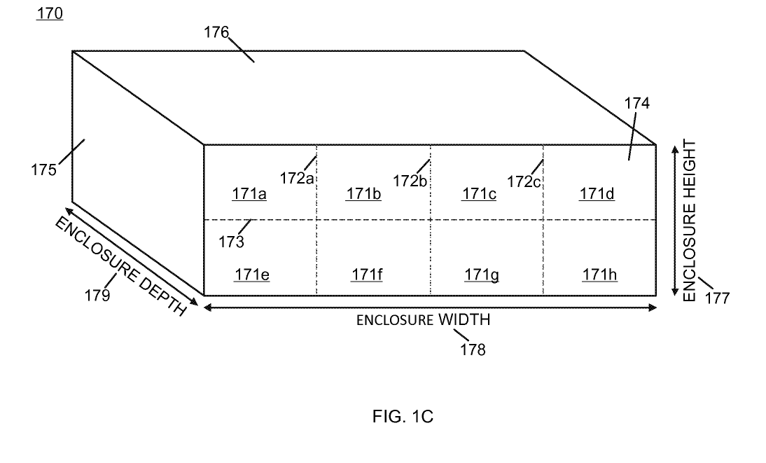

FIG. 1A is an illustration of the frontal view of a plurality of circuit boards 100 of various sizes. All of the circuit boards shown in FIG. 1A are of substantially the same depth (other than small differences due to manufacturing tolerances). Circuit board 110 is a circuit board whose width is a first circuit board width and whose height is a first circuit board height. Circuit board 120 is a circuit board whose width is a second circuit board width and whose height is a first circuit board height. Circuit board 125 is a circuit board whose width is a third circuit board width and whose height is a first circuit board height. Circuit board 130 is a circuit board whose width is a fourth circuit board width and whose height is a first circuit board height. Circuit board 140 is a circuit board whose width is a first circuit board width and whose height is a second circuit board height. Circuit board 150 is a circuit board whose width is a second circuit board width and whose height is a second circuit board height.

Circuit board 120 is at least twice the width of circuit board 110. Circuit board 130 is at least twice the width of circuit board 120, and at least four times the width of circuit board 110. Circuit board 125 is at least three times the width of circuit board 110. Circuit board 140 is substantially the same width (other than small differences due to manufacturing tolerances) as circuit board 110, but it is at least twice the height of circuit board 110. Circuit board 150 is substantially the same width as circuit board 120 (other than small differences due to manufacturing tolerances), but it is at least twice the height of circuit board 120.

In addition to the circuit boards depicted in FIG. 1A, other size and shape circuit boards are possible. For instance, a circuit board that is at least twice the height of circuit board 130 is possible. Such a circuit board may occupy the entire interior cavity of a given enclosure.

FIG. 1B shows a three dimensional perspective view of circuit boards 110, 120, and 140. As can be seen, all three circuit boards are of substantially the same depth 163 (other than small differences due to manufacturing tolerances). In addition, circuit boards 110 and 120 are of substantially the same circuit board height 161 (other than small differences due to manufacturing tolerances), while circuit board 140 is of the second circuit board height 165. Lastly, circuit boards 110 and 140 are of the first circuit board width 162, while circuit board 120 is of the second circuit board width 164.

FIG. 1C shows a three dimensional view of an example embodiment of an enclosure 170 used to house circuit boards. The enclosure is comprised of a top exterior 176, a first side exterior 175, a second side exterior (not shown), a rear exterior (not shown), a bottom exterior (not shown), and a front interior cavity 174. The enclosure dimensions include an enclosure height 177, an enclosure width 178, and an enclosure depth 179. In this example embodiment, the interior of the enclosure cavity 174 is divided into eight sub-cavities 171a-h, as indicated by the dashed vertical lines 172a-c and dashed horizontal line 173. Each of the sub-cavities may be approximately of a first circuit board width 162 and a first circuit board height 161. Therefore, with the inclusion of structural support, up to eight circuit boards 110 of a first circuit board width and a first circuit board height may be housed by the enclosure 170.

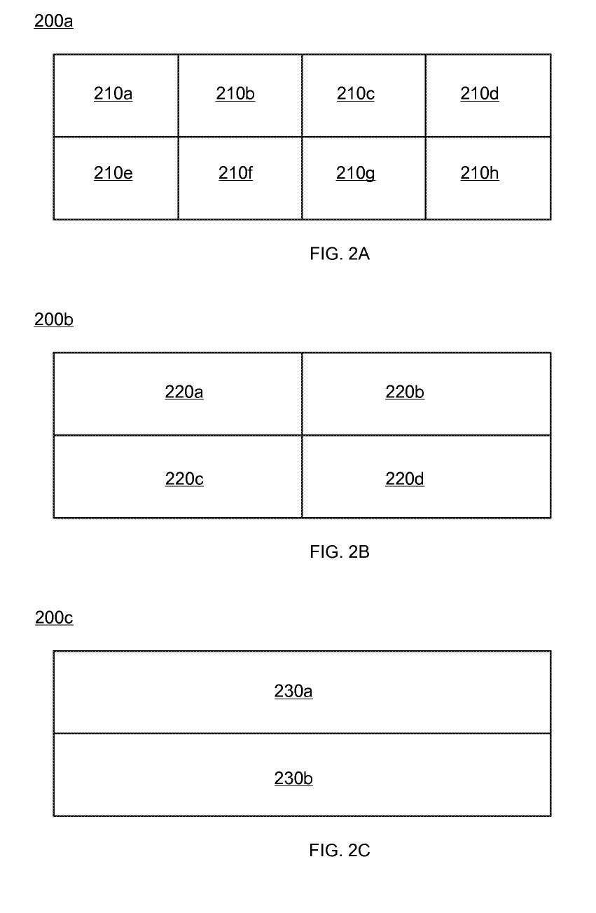

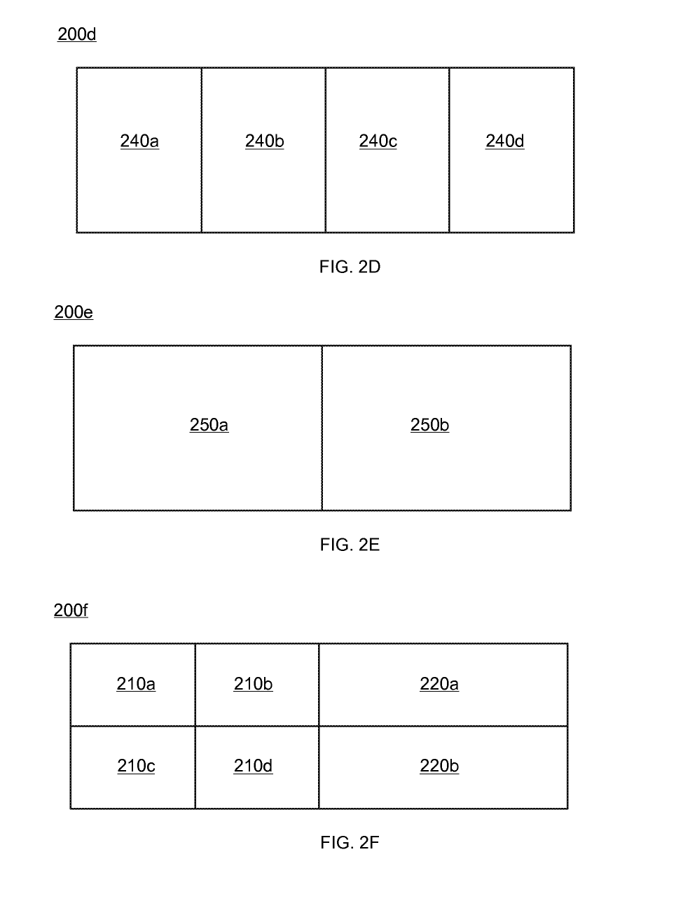

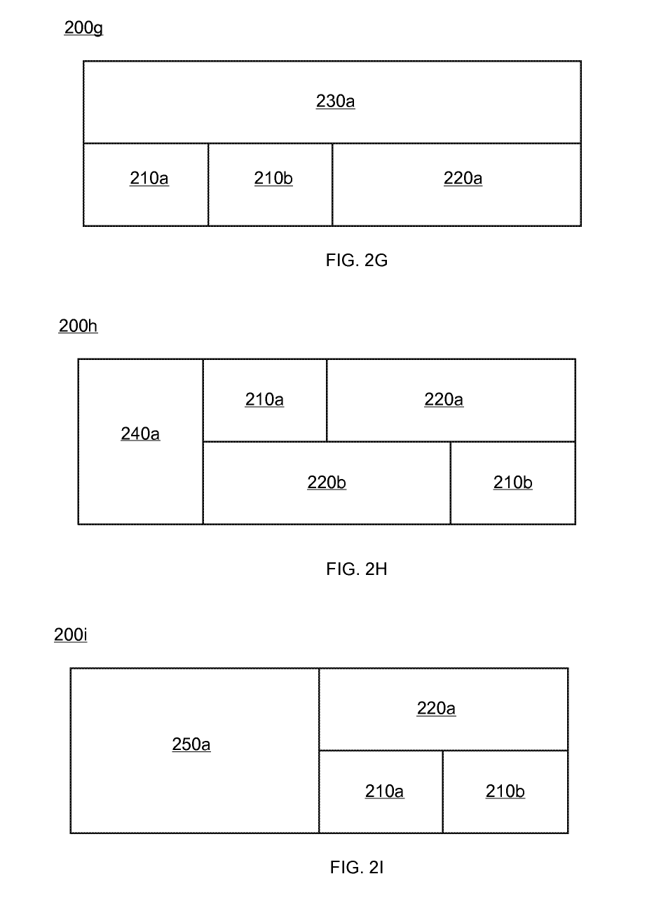

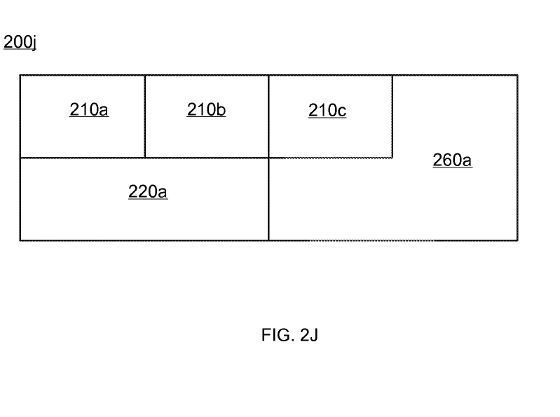

With the inclusion of structural support, other combinations of circuit boards may be housed by the enclosure 170. FIG. 2A through FIG. 2J are used to illustrate some possible configurations of the enclosure 170.

The enclosure 200a, illustrated in FIG. 2A, shows the front view of an enclosure 170 configured to house eight circuit boards. Locations 210a-h within the interior of the enclosure 200a are able to house circuit boards 110 that are a first circuit board width and a first circuit board height.

The enclosure 200b, illustrated in FIG. 2B, shows the front view of an enclosure 170 configured to house four circuit boards. Locations 220a-d within the interior of the enclosure 200b are able to house circuit boards 120 that are a second circuit board width and a first circuit board height.

The enclosure 200c, illustrated in FIG. 2C, shows the front view of an enclosure 170 configured to house two circuit boards. Locations 230a-b within the interior of the enclosure 200c are able to house circuit boards 130 that are a fourth circuit board width and a first circuit board height.

The enclosure 200d, illustrated in FIG. 2D, shows the front view of an enclosure 170 configured to house four circuit boards. Locations 240a-d within the interior of the enclosure 200d are able to house circuit boards 140 that are a first circuit board width and a second circuit board height.

The enclosure 200e, illustrated in FIG. 2E, shows the front view of an enclosure 170 configured to house two circuit boards. Locations 250a-b within the interior of the enclosure 200e are able to house circuit boards 150 that are a second circuit board width and a second circuit board height.

The enclosure 200f, illustrated in FIG. 2F, shows the front view of an enclosure 170 configured to house six circuit boards. Locations 210a-d within the interior of the enclosure 200f are able to house circuit boards 110 that are a first circuit board width and a first circuit board height. Locations 220a-b within the interior of the enclosure 200f are able to house circuit boards 120 that are a second circuit board width and a first circuit board height.

The enclosure 200g, illustrated in FIG. 2G, shows the front view of an enclosure 170 configured to house four circuit boards. Locations 210a-b within the interior of the enclosure 200g are able to house circuit boards 110 that are a first circuit board width and a first circuit board height. Location 220a within the interior of the enclosure 200g is able to house circuit board 120 that is a second circuit board width and a first circuit board height. Location 230a within the interior of the enclosure 200g is able to house circuit board 130 that is a fourth circuit board width and a first circuit board height.

The enclosure 200h, illustrated in FIG. 2H, shows the front view of an enclosure 170 configured to house four circuit boards. Locations 210a-b within the interior of the enclosure 200h are able to house circuit boards 110 that are a first circuit board width and a first circuit board height. Locations 220a-b within the interior of the enclosure 200h is able to house circuit boards 120 that are a second circuit board width and a first circuit board height. Location 240a within the interior of the enclosure 200h is able to house circuit board 140 that is a first circuit board width and a second circuit board height.

The enclosure 200i, illustrated in FIG. 2I, shows the front view of an enclosure 170 configured to house four circuit boards. Locations 210a-b within the interior of the enclosure 200i are able to house circuit boards 110 that are a first circuit board width and a first circuit board height. Location 220a within the interior of the enclosure 200i is able to house circuit board 120 that is a second circuit board width and a first circuit board height. Location 250a within the interior of the enclosure 200i is able to house circuit board 150 that is a second circuit board width and a second circuit board height.

The enclosure 200j, illustrated in FIG. 2J, shows the front view of an enclosure 170 configured to house five circuit boards. Locations 210a-c within the interior of the enclosure 200j are able to house circuit boards 110 that are a first circuit board width and a first circuit board height. Location 220a within the interior of the enclosure 200j is able to house circuit board 120 that is a second circuit board width and a first circuit board height. Location 260a within the interior of the enclosure 200j is able to house a circuit board that has an irregular shape.

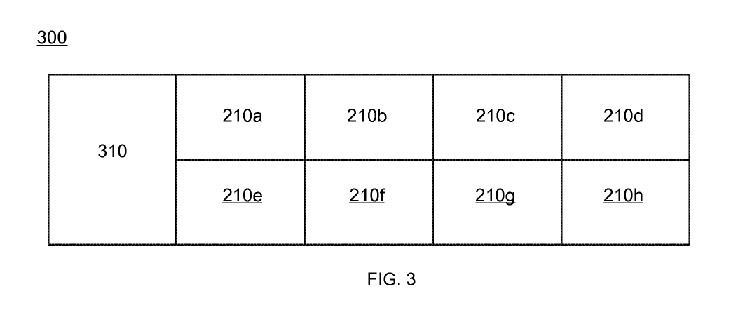

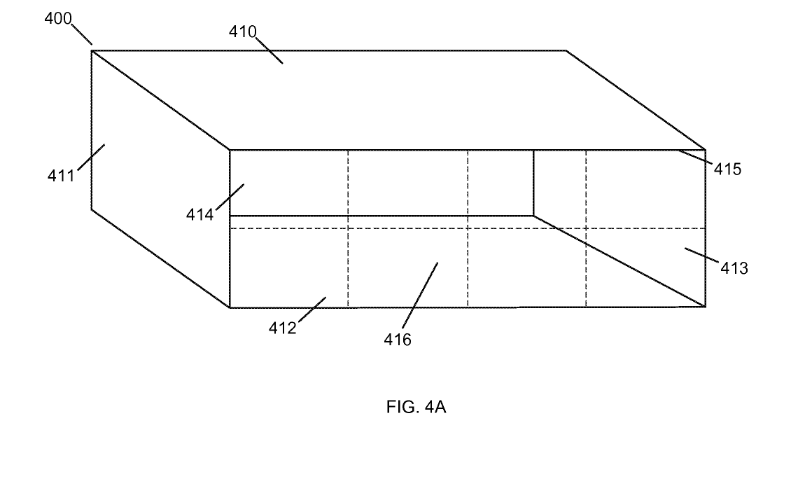

An enclosure comprising of configurable circuit board sub-cavities may also comprise of at least one fixed cavity that is not configurable. Such a location would always house a circuit board of the same size. FIG. 3 shows the front view of an enclosure 300 with a single non-configurable fixed cavity 310 and eight configurable sub-cavities 210a-h.

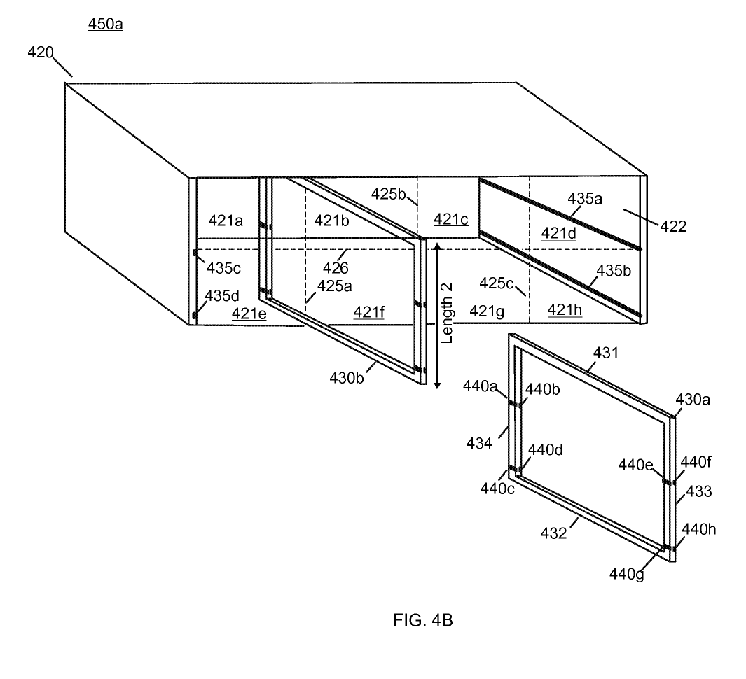

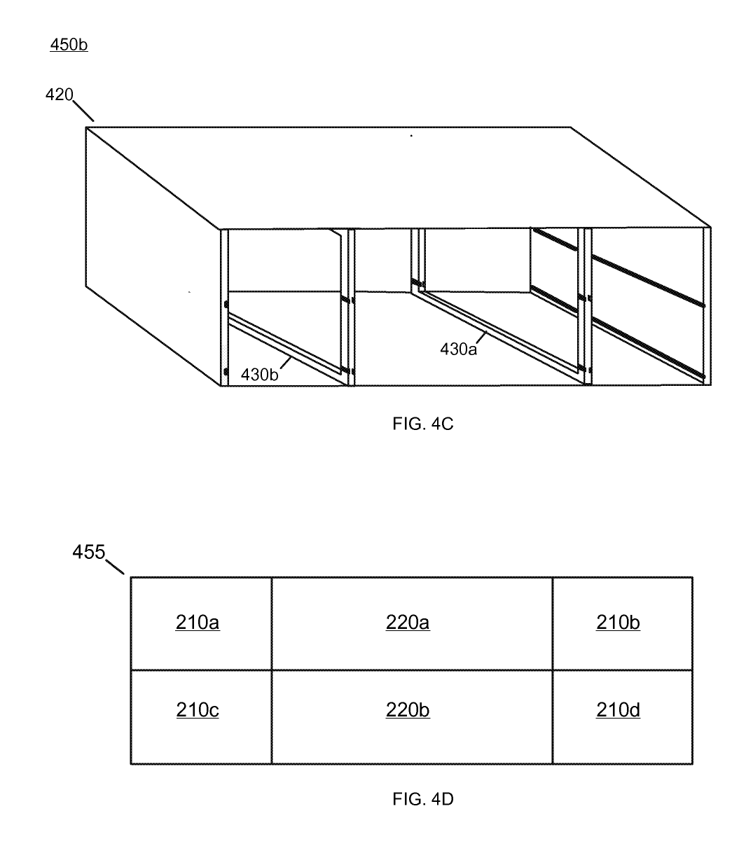

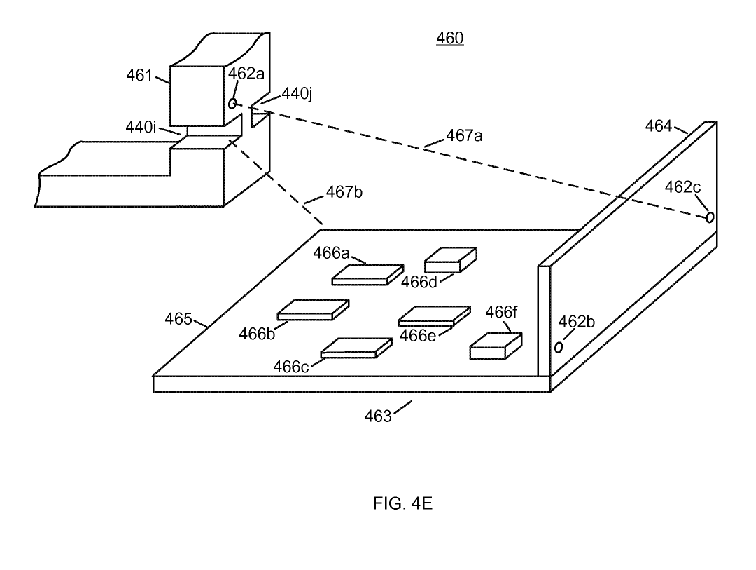

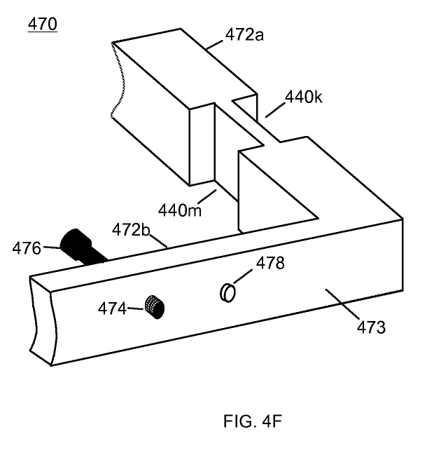

FIG. 4A shows the front view of the enclosure 400 that is substantially the same as enclosure 170 shown in FIG. 1C. Enclosure 400 illustrates the various interior and exterior surfaces of the enclosure. The enclosure contains a top exterior 410, a first side exterior 411, a second side exterior (not shown), a rear exterior (not shown), a bottom exterior (not shown), a first side interior (not shown), a second side interior 413, a bottom interior 412, a rear interior 414, and a top interior 415. The top, bottom, rear, and side interior and exterior surfaces are connected together to form the interior cavity 416.

FIG. 4B shows a system for housing circuit boards 450a, comprising of an enclosure 420 with an interior cavity 422 and at least one positionable enclosure partition 430a. The system 450a provides a means of housing a plurality of circuit boards that may substantially differ in at least two physical dimensions. An example of such a plurality of circuit boards are circuit boards 110, 120, 125, 130, 140, and 150 depicted in FIG. 1A and FIG. 1B. The interior cavity 422 of the enclosure 420 is subdivided into eight sub-cavities 421a-h, as indicated by the dashed vertical lines 425a-c and dashed horizontal line 426 in FIG. 4B. These eight sub-cavities 421a-h are substantially the same as those sub-cavities described in reference to the enclosure 170. With the proper structural support a single sub-cavity may be used to form a single circuit board housing—capable of housing a single circuit board. For instance, once enclosure partition 430b is fully inserted into enclosure 420 at location 425a, sub-cavity 421e, in combination with enclosure partition 430b and the left side interior of 420, form a circuit board housing capable of housing a circuit board of the dimensions of circuit board 110. The so formed circuit board housing has a first circuit board dimension (spanning from the left interior side of enclosure 420 to partition 430b) of a first circuit board width, and a second circuit board dimension (spanning from the bottom interior of enclosure 420 to halfway up the cavity 422, or to the horizontal dashed line 426) of a first circuit board height. In addition sub-cavities may be joined together to form larger circuit board housings. For instance, once enclosure partitions 430a and 430b are fully inserted into enclosure 420 (at locations 425a and 425c), as indicated in FIG. 4C, sub-cavities 421f and 421g, in combination with enclosure partitions 430a and 430b, form a circuit board housing capable of housing a circuit board of the dimensions of circuit board 120. The so formed circuit board housing has a first circuit board dimension (spanning from partition 430b to partition 430a) of a second circuit board width, and a second circuit board dimension (spanning from the bottom interior of enclosure 420 to halfway up the cavity 422, or to the horizontal dashed line 426) of a first circuit board height. The value of the third dimension of the circuit board housings (corresponding to the depth 179 of the enclosure) may be a fixed value for all circuit board housings within the enclosure 420.

In FIG. 4B, the height of the positionable enclosure partition 430b is referred to as the length of the positionable enclosure partition. This is a more general term than height, since an embodiment of this invention may include an enclosure wherein enclosure partitions are inserted horizontally into an enclosure (rather than vertically). For purposes of this application, the length of the enclosure partitions 430a 430b are length 2 (which is equal to the height of two enclosure sub-cavities, or approximately equivalently equal to a second circuit board height—as described in reference to the circuit boards 100).

In general, the interior cavity 422 may be segmented into an array of sub-cavities 421a-h comprised of n rows (n=2 for cavity 422) and m columns (m=4 for cavity 422), and an enclosure partition 430 may be positioned between any two columns of the array (at locations 425a-c for instance), in order to form one or more circuit board housings. More specifically, if a single enclosure partition is placed between two columns of sub-cavities, the enclosure cavity is effectively divided into a first half (to the left of the partition) and a second half (to the right of the partition). This results in a first set of circuit board housings (to the left of the partition) and a second set of circuit board housings (to the right of the partition). If each circuit board housing is a single sub-cavity in height, then the placement of a single enclosure partition results in the formation of a first set of n circuit board housings (to the left of the partition) and a second set of n circuit board housings (to the right of the partition). Each of the n circuit board housings to the left of the partition has a first dimension (the width) whose value may be substantially equal to the width of i columns, while each of the n circuit board housings to the right of the partition has a first dimension (the width) whose value may be substantially equal to the width of m−i columns (where i is any integer in the range of 1 to m−1). As an example, if an enclosure partition is placed at location 425a within enclosure 420, then i=1, and m−i=4−1=3, resulting in a first dimension (width) whose value is 1 column wide (for the circuit board housings to the left of the partition) and a first dimension whose value is equal to 3 columns wide (for the circuit boards to the right of the partition).

The system for housing circuit boards 450a is able to be configured to simultaneously house circuit boards that differ in two dimensions. Such a configuration is depicted in FIG. 2I, wherein circuit board housing 250a (capable of housing circuit board 150) is at least twice the height and width of circuit board housing 210a (capable of housing circuit board 110). Alternatively, a first enclosure may be configured to house a first circuit board of a first circuit board width and a first circuit board height (200a), and a second enclosure may be configured to house a second circuit board of a second circuit board width and a second circuit board height (200e). In yet another alternative, a first enclosure may be configured to house a first circuit board of a first circuit board width and a first circuit board height (200a), a second enclosure may be configured to house a second circuit board of a second circuit board width and a first circuit board height (200b), and a third enclosure may be configured to house a third circuit board of a first circuit board width and a second circuit board height (200d). Alternatively, a first enclosure may be configured to a house both a first circuit board of a first circuit board width and a first circuit board height and a second circuit board of a first circuit board width and a second circuit board height, and a second enclosure may be configured to house a third circuit board of a second circuit board width and a first circuit board height.

Therefore, for an enclosure that can be configured to house circuit boards that differ in a least two dimensions, one dimension may include the dimension of circuit board width, and one dimension may include the dimension of circuit board height. The enclosure may be configured to house circuit boards of at least a first circuit board width, a second circuit board width, and a third circuit board width. Additionally, the enclosure may further be configured to house circuit boards of at least a first circuit board height and a second circuit board height.

The enclosure 420 may be augmented with at least one positionable enclosure partition 430a-b, used to configure the enclosure. FIG. 4B shows one such positionable enclosure partition 430a completely removed from the enclosure 420. The positionable enclosure partition may include, but is not limited to, a top horizontal structure 431, a bottom horizontal structure 432, a right vertical structure 433, and a left vertical structure 434. The top and bottom horizontal structures may be connected together via the left and right vertical structures, as shown in FIG. 4B. Additional vertical structures may be included that span between the top 431 and bottom 432 horizontal structures, and additional horizontal structures may be included that span between the left 434 and right 433 vertical structures.

The at least one positionable enclosure partition may be constructed such that when it is placed within the enclosure the positionable enclosure partition spans the entire height of the enclosure, as illustrated in FIG. 4B, with respect to positionable enclosure partition 430b. Such a positionable enclosure partition may be the height of the second circuit board height, and may be referred to as a full-height partition. FIG. 4B shows positionable enclosure partition 430b partially positioned within the enclosure 420. The positionable enclosure partition 430b may be substantially the same as positionable enclosure partition 430a (other than small differences due to manufacturing tolerances). The dimension of the enclosure partition 430a-b that spans between the top and bottom of the enclosure is referred to as the length of the partition. Therefore, the length of the partition 430a (Length 2) is substantially equal to the height of two sub-cavities (or equivalently is substantially equal to the height of the “second circuit board height”, as defined in reference to the circuit boards of FIG. 1A.

FIG. 4C illustrates a system 450b where the two full-height positionable enclosure partitions 430a and 430b are fully inserted into the enclosure at the vertical positions of 425a and 425c of the enclosure. The enclosure 420 illustrated in FIG. 4B can accommodate three of the full-height enclosure partitions 430a-b. An enclosure partition may be placed at the three locations 425a-c indicated by the vertical dashed lines in FIG. 4B. By placing full-height enclosure partitions into all three locations 425a, 425b, and 425c of the enclosure 420, the enclosure can accommodate eight circuit boards with a first circuit board width and a first circuit board height (110), as shown in FIG. 2A.

The positionable enclosure partitions may further include circuit board guides 440a-h, used to guide a circuit board into position within the enclosure. (Typically, it will be the printed circuit board of the PCBA that slides into the circuit board guides, but this does not always have to be the case. For some circuit board assemblies, another structure within the PCBA may be used to slide into the circuit board guides.) The right and left interior walls of the enclosure (i.e., the side interiors) may also include circuit board guides 435a-b, and 435c-d respectively. These circuit board guides (435a-b, and 435c-d) may be located on a non-movable (i.e., non-positionable) structure within the enclosure. Alternatively, the structure that they are located on may be movable (positionable). The circuit board guides 435a-d may span the entire depth of the enclosure, as indicated in FIG. 4B. Once the full-height positionable enclosure partition 430a is fully inserted into location 425c (as shown in FIG. 4C, a first circuit board 110 can be inserted into the lower circuit board guides of 435b, 440d, and 440h. In a similar manner, a second circuit board 110 can be inserted into the upper circuit board guides of 435a, 440b, and 440f. Either the upper or lower circuit board 110 may be inserted into the enclosure first. Furthermore, either the upper or lower circuit board may reside within the vertical space to the right of 425c without the other circuit board being present. Alternatively, a single circuit board 140 may be placed in the in the vertical space to the right of 425c, wherein the circuit board 140 may utilize either the upper circuit board guides 435a, 440b, 440f or the lower circuit board guides 435b, 440d, 440h. Alternatively, when the single circuit board 140 is placed in the vertical space to the right of 425c, it may use both the upper circuit board guides 435a, 440b, 440f and the lower circuit board guides 435b, 440d, 440h.

The circuit board guides may be implemented in the form of slots on the positionable enclosure partitions (and within the left and right side interiors of the enclosure cavity). A more detailed view of one possible implementation of such slots is shown by the partial enclosure partition and circuit board 460 in FIG. 4E. In FIG. 4E 460 is comprised of the lower right corner of a positionable enclosure partition 461, and the circuit board 463. The partition 461 comprises of circuit board guides implemented in the form of at least a left 440i and a right 440j slot, and may further include at least one screw hole 462a used for the attachment of a front panel 464, or some other structure. The left and right slots 440i-j may be in the form of substantially rectangular cavities in the vertical structure of the partition 461, as indicated in FIG. 4E. Alternatively, the slot structure may have a substantially concave shape (not shown). The circuit board 463 is comprised of PCB 465, electrical and optoelectronic components 466a-f, and front panel 464. In one embodiment, the PCB 465 of the circuit board 463 slides into the circuit board guide formed by slot 440i in the vertical structure of positionable enclosure partition 461, as indicated by the dashed line 467b. In an alternative embodiment (not shown), a structure on the circuit board other than the PCB (such as, for example, a metal plate) may be slid into the board guide slot 440i.

The front panel 464 may further include at least one hole 462c used to attach the front panel to a positionable enclosure partition, or some other structure of the enclosure. FIG. 4E illustrates, via dashed line 467a, how the hole 462c on the front panel 464 would line up with a similar hole 462a on the positionable enclosure partition 461. The hole 462a on the positionable enclosure partition may be a threaded hole, allowing for the use of a threaded screw to be placed through the front of the front panel 464 through hole 462c, and then screwed into the threaded hole 462a in order to secure the front panel to the positionable enclosure partition. The front panel 464 may further comprise of at least a second hole 462b for purposes of securing the front panel to a second positionable or non-positionable enclosure partition or other structure within the enclosure.

The circuit boards 110, 120, 125, 130, 140, and 150 may additionally contain an electrical connector at the rear of the circuit boards (not shown). The electrical connector on the circuit board may mate with an electrical connector on a backplane (not shown) that may be located at the rear of the interior cavity of the enclosure. The backplane may be physically divided into eight sub-sections, corresponding to the eight sub-cavities of the enclosure cavity indicated by the dashed lines in FIGS. 4A and 4B. Each of the eight sub-sections on the back plane may contain at least one electrical connector. Each of the eight sub-sections of the enclosure backplane may additionally contain a guide pin used to further guide a circuit board into position within the enclosure, while allowing the electrical connector on the circuit board to fully engage with the electrical connector on the back plane. The guide pin on the backplane is inserted into a guide pin socket on the circuit board in order to assist in guiding the circuit board into its proper position within the enclosure.

Once all three full-height positionable enclosure partitions are placed into locations 425a-c, eight circuit boards 110 of a first circuit board width and a first circuit board height may be inserted into eight circuit board housings of the enclosure. Since, a given full-height positionable enclosure partition contains lower left circuit board guides 440c,g, upper left circuit board guides 440a,e, lower right circuit board guides 440d,h, and upper right circuit board guides 440b,f, a single full-height positionable enclosure partition provides circuit board guides for up to four circuit boards (two on either side of the partition).

When eight circuit boards 110 are placed within the enclosure 420 using three full-height positionable enclosure partitions located at predetermined enclosure locations 425a, 425b, and 425c, the two most left circuit boards 110 are located between the left interior wall of the enclosure and the enclosure partition at location 425a. Similarly, the second set of two circuit boards are placed between the enclosure partitions located at locations 425a and 425b within the enclosure, the third set of two circuit boards are placed between the enclosure partitions located at locations 425b and 425c within the enclosure, and the right most two circuit boards are placed between the right interior wall of the enclosure and the enclosure partition located at location 425c.

When the enclosure is partitioned with three full-height positionable enclosure partitions, such that eight circuit boards 110 of a first circuit board width and a first circuit board height can be placed within the enclosure, the eight circuit boards may be populated within the enclosure in any desired order. Furthermore, a given circuit board may be placed into the enclosure without affecting the electrical or optical operation of any existing circuit boards within the enclosure.

In addition, to accommodating the eight-circuit-board-structure 200a, when three full-height positionable enclosure partitions are placed within enclosure 420, the structure 200d shown in FIG. 2D can also be accommodated. In other words, four circuit boards 140 of a first circuit board width and a second circuit board height can be inserted into the enclosure. The circuit board 140 would likely only utilize the lower circuit board guides 435b,d 440c,g 440d,h, but may additionally utilize the upper circuit board guides 435a,c 440a,e 440b,f. Also, the physical enclosure partitioning created by inserting three full-height positionable enclosure partitions into the enclosure 420 may also be used to accommodate mixes of circuit boards 110 and 140 in the enclosure. For instance, a single circuit board 140 may be placed to the left of the enclosure partition located at location 425a, and six circuit boards 110 may be placed to the right of the enclosure partition located at location 425a.

The configuration 200b, shown in FIG. 2B can be obtained by placing only a single full-height positionable enclosure partition into the enclosure 420. The enclosure partition would be placed into the location 425b. This configuration would allow four circuit boards 120 of a second circuit board width and a first circuit board height to be placed within the enclosure. Alternatively, the configuration 200e that accommodates two circuit boards 150, is also accommodated by placing a single full-height positionable enclosure partition into location 425b. Lastly, the single full-height enclosure partition (placed at location 425b) can accommodate one circuit board 150 and two circuit boards 120 (not shown).

By placing only two full-height positionable enclosure partitions into the enclosure 420, configuration 200f shown in FIG. 2F may be accommodated. For the FIG. 2F configuration 200f, the two full-height enclosure partitions are placed at locations 425a and 425b. This allows four circuit boards 110 of a first circuit board width and a first circuit board height to be placed to the left of the partition at 425b, and two circuit boards 120 of a second circuit board width and a first circuit board height to be placed to the right of the enclosure partition at location 425b. By moving the two full-height positionable enclosure partitions to other locations within the enclosure, the wider circuit boards 120 can be located in two other locations within the enclosure. For instance, by placing the two full-height enclosure partitions at locations 425a and 425c, the configuration shown in FIGS. 4C and 4D may be achieved. The configuration 455 shown in FIG. 4D comprises of four circuit board housings 210a-d that are capable of housing circuit boards 110, and two circuit board housings 220a-b that are capable of housing circuit boards 120. The configurations shown in FIGS. 2F and 4C can also be used to accommodate a combination of four circuit boards 110 and a single circuit board 150, or two circuit boards 140 and a single circuit board 150, or two circuit boards 140 and two circuit boards 120.

As shown in the configuration 200c, with no enclosure partitions installed, two circuit boards 130 of a fourth circuit board width and a first circuit board height can be accommodated.

Once a full-height enclosure partition is slid into the enclosure, the enclosure partition may be attached to the top interior 415 and or bottom interior 412 of the enclosure. The full-height enclosure partition may be attached to the enclosure using at least one screw. The at least one screw may be a thumb-screw that can be tightened using ones thumb and finger only. Additionally, the thumbs screw could contain an Allen wrench slot that could be used to further tighten the screw using an Allen wrench. The screw could further be permanently attached to the positionable enclosure partition so that when the screw is unscrewed it does not separate from the positionable enclosure partition.

The screw used to attach the partition to the enclosure may attach the partition to the enclosure from the interior of the enclosure or from the exterior of the enclosure. If the screw is attached from the exterior of the enclosure, then the procedure to install the enclosure partition would be to first slide the enclosure partition into the enclosure, and then install the at least one screw by first inserting the screw through a hole in either the top or bottom of the enclosure (or both, when two screws are used), and then screwing the screw into a threaded hole on the top or the bottom of the enclosure partition. A washer may be placed between the screw head and the exterior of the enclosure. The washer may be a lock washer. For additional stability, four or more screws could be used.

If the screw used to attach the partition to the enclosure is attached from the interior of the enclosure, it's desirable to use a screw that is permanently (or semi-permanently) attached to the positionable enclosure partition, so that the screw cannot fall into the enclosure. When attaching the partition to the bottom of the enclosure, the screw could be placed into a hole that goes through the bottom horizontal structure 432 of the enclosure partition, and then screwed into a threaded hole on the bottom of the enclosure. Similarly, when attaching the partition to the top of the enclosure, the screw could be placed into a hole that goes through the top horizontal structure 431 of the enclosure partition, and then screwed into a threaded hole on the top interior of the enclosure.

At least two guide pins may be used to correctly position a positionable enclosure partition within the enclosure. The guide pin may reside on the positionable enclosure partition (in that case a guide pin hole resides on the enclosure top and or bottom interior), or the guide pin may reside on the top and or bottom interior of the enclosure (in that case, a guide hole resides on the positionable enclosure partition). The preferred method is to place the guide pin on the positionable enclosure partition, so that the guide pins do not interfere with circuit boards that are of a second or third circuit board widths. The at least two guide pins could be stationary pins, or they could be spring loaded pins. If the guide pin is a stationary guide pin, the enclosure partition may be first inserted into the enclosure at an angle, and then snapped into place by turning the partition such that it becomes perpendicular to the enclosure top and bottom. If the guide pin is spring loaded, the pin is forced into the guide pin hole using a spring mechanism once the positionable enclosure partition is put into place. If multiple guide pins are utilized, screws may not be required to further hold the positionable enclosure partition into its correct location. Alternatively, a combination of both guide pins and screws may be used to position the enclosure partition and to secure it onto the enclosure. FIG. 4F shows a portion of a positionable enclosure partition 470 comprising at least one vertical structure 472a containing at least two board guide slots 440k 440m, at least one horizontal structure 472b, at least one guide pin 478, and at least one screw 474, wherein the at least one screw penetrates through the bottom exterior 473 of the horizontal structure 472b. The screw 474 is used to attach the positionable enclosure partition to the bottom interior of the enclosure, and may additionally comprise of a thumb screw head 476. The at least one guide pin 478 is positioned within a companion guide pin hole in the bottom interior of the enclosure.

Positionable enclosure partitions that span less than the entire height of the enclosure may also be placed within the enclosure 420. In one embodiment, a positionable enclosure partition that spans half the height of the enclosure (half-height enclosure partition) may be placed within the enclosure 420. For this case, the length of the positionable enclosure partition is substantially equal to a first circuit board height. This half-height positionable enclosure partition may be attached to the top interior of the enclosure (wherein it is not additionally attached to the bottom interior of the enclosure), or the half-height positionable enclosure partition may be attached to the bottom interior of the enclosure (wherein it is not additionally attached to the top interior of the enclosure).

The half-height positionable enclosure partition may optionally contain a guide pin used to guide the enclosure partition into place on the enclosure interior top or bottom. The guide pin may be stationary or spring loaded.

The half-height positionable enclosure partition may be screwed to the enclosure interior top or bottom. The half-height positionable enclosure partition may be screwed to the enclosure using a screw from the exterior of the enclosure (into a threaded hole on the enclosure partition), or the enclosure partition may be screwed to the enclosure using a screw from the interior of the enclosure (into a threaded hole on the enclosure top or bottom). For this later case, the screw may be a thumb screw. The thumb screw may optionally contain an Allen wrench slot.

Alternatively or additionally, both the full-height positionable enclosure partition and the half-height positionable enclosure partition may attach to the back interior cavity of the enclosure.

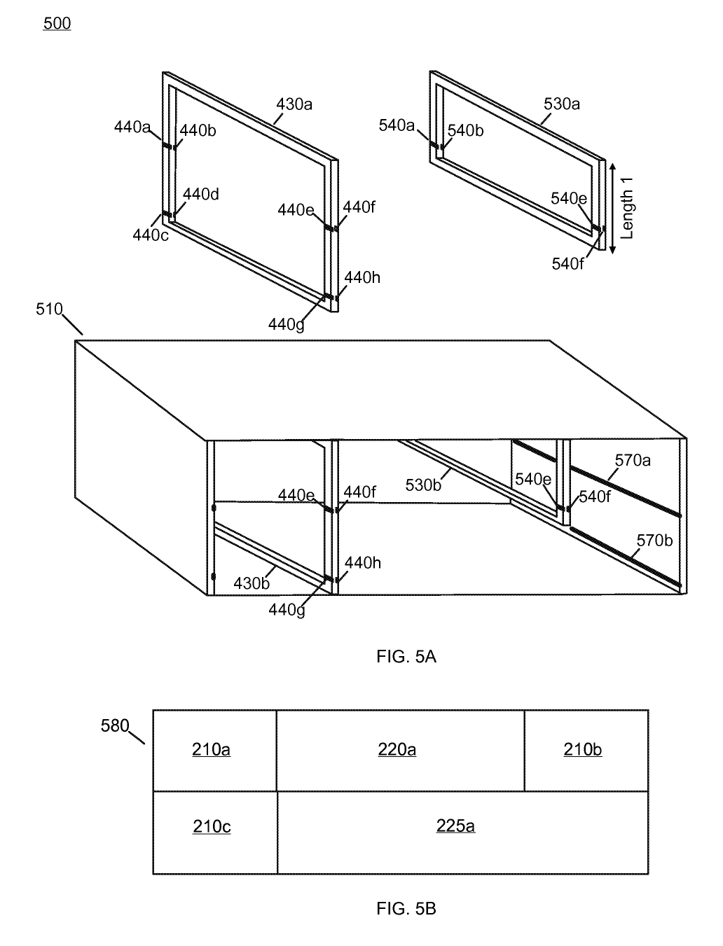

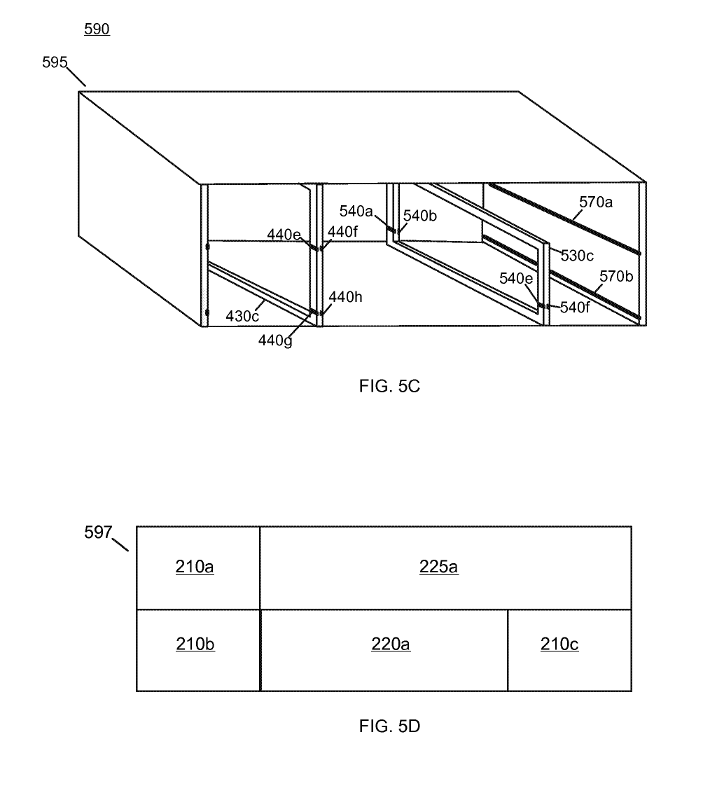

The system for housing circuit boards 500 shown in FIG. 5A is used to illustrate the concept of the half-height positionable enclosure partition. Separate from the enclosure 510, FIG. 5A shows both a full-height positionable enclosure partition 430a and a half-height positionable enclosure partition 530a. As can be seen, the half-height positionable enclosure partition is approximately half the height of the full-height positionable enclosure partition, but the depth of both is substantially the same. Unlike the full-height positionable enclosure partition, the half-height enclosure partition contains only lower circuit board guides 540a-b 540e-f used to guide circuit boards into position within the enclosure. The half-height positionable enclosure partition contains the same size horizontal top and bottom structures as the full-height positionable enclosure partition, but has vertical structures that are half the size of those on the full-height positionable enclosure partition.

The positionable enclosure partitions 530a 530b have a length equal to length 1 (as indicated in FIG. 5A). Therefore, it can be said that the positionable enclosure partitions 530a 530b are approximately half the length of the positionable enclosure partitions 430a and 430b, whose length are of length 2.

The system for housing circuit boards 500 additionally comprises of an enclosure 510, as shown in FIG. 5A. In FIG. 5A, the enclosure 510 contains both a full-height positionable enclosure partition 430b fully inserted into the enclosure, and a half-height positionable enclosure partition 530b fully inserted into the enclosure.

There are six locations where the half-height positionable enclosure partition can be placed within the example embodiment enclosures of 420 and 510. The six locations are those indicated by the top and bottom positions associated with locations 425a, 425b, and 425c in FIG. 4B. For instance, in FIG. 5A, the half-height positionable enclosure partition is placed in the top position of 425c.

FIG. 5B illustrates a configuration resulting from the placement of the full-height positionable enclosure partition 430b (at location 425a), and half-height positionable enclosure partition 530b (at the top of location 425c), as shown in FIG. 5A. As can be seen, the configured enclosure 580 comprises of three circuit board housings 210a-c that are capable of housing circuit boards 110, one circuit board housing 220a that is capable of housing circuit board 120, and one circuit board housing 225a that is capable of housing circuit board 125. Five circuit boards circuit boards would be placed in the corresponding five circuit board housings created in part by the two positionable enclosure partitions.

FIG. 5C illustrates the placement of the half-height positionable enclosure partition 530c on the bottom of the enclosure, while FIG. 5D shows one resulting enclosure configuration 597. The configuration 597 comprises of three circuit board housings 210a-c that are capable of housing circuit boards 110, one circuit board housing 220a that is capable of housing circuit board 120, and one circuit board housing 225a that is capable of housing circuit board 125.

It should be noted, that for one embodiment, a maximum of three half-height positionable enclosure partitions 530 may be placed within the enclosure 420, 510, or 590. This is because if a half-height positionable enclosure partition is placed in either the top or bottom locations corresponding to locations 425a, 425b, or 425c, then a corresponding half-height positionable enclosure partition may not be placed opposite the half-height positionable enclosure partition in those locations. In this embodiment, if a partition that spans the entire height of the enclosure is required at a location, a full-height positionable enclosure partition should be used. In an alternative embodiment, two half-height positionable enclosure partitions may be placed opposite one another (at a given location 425a, 425b, or 425c) in order to form the functionality associated with the full-height positionable enclosure partition. This later embodiment provides for additional flexibility when an enclosure is only partially populated initially.

As can be seen, from FIG. 5A and FIG. 5C, the circuit board guides on the half-height positionable enclosure partition provides guides for two circuit boards—one on either side of the enclosure partition.

The configuration 200c uses no full-height positionable enclosure partitions and no half-height positionable enclosure partitions. The configurations 200a and 200d use three full-height positionable enclosure partitions and no half-height positionable enclosure partitions. The configuration 200f uses two full-height positionable enclosure partitions and no half-height positionable enclosure partitions. The configurations 200b and 200e use one full-height positionable enclosure partition and no half-height positionable enclosure partitions. The configuration 200g uses no full-height positionable enclosure partitions and two half-height positionable enclosure partitions (attached to the bottom interior). The configurations 200h and 200j use one full-height positionable enclosure partition and two half-height positionable enclosure partitions. The configuration 200i uses one full-height positionable enclosure partition and one half-height positionable enclosure partition. In all configurations shown, no more than three positionable enclosure partitions are used.

From FIG. 4E, it is evident that the front panel 464 of the circuit board 463 overlaps the front face of the enclosure partition 461 once the circuit board is fully inserted into the slots of the enclosure partition. This has the benefit of creating a tight Electromagnetic Interference (EMI) seal between the circuit board and the enclosure. Therefore, the preferred embodiment is to match the height of the inserted circuit board to the length of the enclosure partition(s) the circuit board is attached to. For example, suppose enclosure 420 is populated with four circuit boards of the type 140 (second circuit board height, and first circuit board width). Even if the circuit board 140 needs only a bottom set of circuit board guides (440c, 440g, for example), a full-height enclosure partition is used. This provides a tight EMI seal over the entire height of the four circuit boards. Based upon this, the length of the positionable enclosure partition determines the range of one dimension of the circuit board housing formed in part by the enclosure partition. For example, if a positionable enclosure partition with a length equal to length 1 (i.e., a half-height partition) is placed at location 425a of enclosure 420, a circuit board housing with a height of one sub-cavity is formed to the left of the partition, and therefore only circuit board 110 may be placed in the circuit board housing to the left of the partition at location 425a (and not circuit board 140). However, if a positionable enclosure partition with a length equal to length 2 (i.e., a full-height partition) is placed at location 425a of enclosure 420, then to the left of the partition, either two circuit board housings can be accommodated (each with a height of one sub-cavity), or a single circuit board housing can be accommodated (with a height of two sub-cavities). In this case, the range of the value of the height-dimension of the formed circuit board housing ranges from a height of one sub-cavity to a height of two sub-cavities. Correspondingly the range of the value of the height-dimension of the circuit boards within the formed circuit board housings ranges from a height of one sub-cavity to a height of two sub-cavities. For the enclosure partition of a length equal to length 1, the range of the value of the height-dimension of the formed circuit board housing ranges from a height of one sub-cavity to a height of one sub-cavity.

As is evident from the previous discussions and drawings, the width dimension of a given circuit board housing is dependent upon the position of the positionable enclosure partition (within the enclosure) used to form the housing. For example, when a positionable enclosure partition is placed at location 425a, the width of the corresponding circuit board housing to the left of the partition is one sub-cavity. When the positionable enclosure partition is placed at location 425b, the width of the corresponding circuit board housing to the left of the partition is two sub-cavities. When the positionable enclosure partition is placed at location 425c, the width of the corresponding circuit board housing to the left of the partition is three sub-cavities.

In the example embodiment of enclosure 420, one may designate the width of the circuit board housing as a first dimension, and the height of the circuit board housing as a second dimension. Then, an example embodiment is a system for housing circuit boards, comprising of an enclosure, one or more positionable enclosure partitions, and one or more circuit board housings (located within the enclosure). The circuit board housings are formed in part by the one or more enclosure partitions. Each of the circuit board housings has at least a first dimension and a second dimension—each of which may be one of a plurality of predetermined values. The position of one or more enclosure partitions determines the value of the first dimension of a given circuit board housing, while the length of one or more partitions bounds the value of the second dimension of the given circuit board housing, and therefore determines the range of values of the second dimension of the circuit board housing.

The system may provide a number of predetermined locations within the enclosure where the partitions may be placed (such as at locations 425a, 425b, and 425c). Since the enclosure partitions can be positioned at these different locations within the cavity of the enclosure, the enclosure partitions are said to be positionable.

Since the positionable enclosure partitions so described are narrow and flat in physical structure, the enclosure partitions can be described as substantially planar in form.

A given system may contain multiple enclosure partitions. These partitions can be substantially the same length, or they may be of substantially different lengths. In general, an embodiment of a system for housing circuit boards may comprise of a plurality of positionable enclosure partitions of a variety of lengths.

Each enclosure partition may provide mechanical support for circuit boards placed inside the circuit board housings formed in part by the enclosure partition. This mechanical support may be in the form of circuit board guides located on both sides of the enclosure partitions, wherein the circuit boards are guided into predefined locations within the enclosure (circuit board housings) by way of these circuit board guides, and then the circuit board guides are used to physically support the circuit boards once the circuit boards are fully inserted into the enclosure. Additional mechanical support is provided by the enclosure partitions by way of the optional screw holes 462a contained within the front portion of the enclosure partitions. These screw holes can be used to attach the front face plate of a given circuit board to the enclosure partition, thereby providing an additional level of mechanical support to the circuit board. Therefore, the system provides a means for securing a circuit board to one or more partitions, and this means may be of the form of a screw through the front panel of the circuit board and into a threaded hole on the front facing surface of the enclosure partition.

The system provides a means for guiding circuit boards into predetermined locations within the enclosure. The means may be of the form of circuit board guides located on each enclosure partition, and located on the interior side surfaces of the enclosure.

Embodiments of the invention include a means for attaching the positionable enclosure partitions to the interior cavity of the enclosure. One means is to use one or more screws to attach the partition to the top and or bottom interior surfaces of the enclosure. The screw may originate from the exterior of the enclosure, or it may originate from the interior of the enclosure.

A system for housing circuit boards may comprise of only a single predetermined location for placement of an enclosure partition. However, in a preferred embodiment, the system comprises of a plurality of predetermined locations for placement of enclosure partitions (locations 425a-c, for example).

An embodiment of a system for housing circuit boards may provide a means for guiding its enclosure partitions into predefined locations within the enclosure. One means involves using at least one guide pin on the enclosure partitions to aid in guiding the partitions into corresponding guide holes on the top or bottom of the interior surfaces of the enclosure.

Although previous example embodiments designated the width of the circuit board housing as a first dimension, and the height of the circuit board housing as a second dimension, other example embodiments may designate the height of the circuit board housing as a first dimension, and the width of the circuit board housing as a second dimension.

Embodiments of the invention include a method for housing circuit boards within an enclosure. The method includes creating at least one circuit board housing within the enclosure using at least one positionable enclosure partition. The circuit board housing created may be of a variety of sizes, including a variety of fixed values for a first dimension, and a variety of fixed values for a second dimension. The method additionally includes choosing a positionable enclosure partition of a particular length, wherein the length of the positionable enclosure partition determines a predetermined range of values of the first dimension of the circuit board housing. The method further includes placing the at least one positionable enclosure partition at one of a plurality of predetermined locations within the enclosure, wherein the location chosen determines the value of a second dimension of the circuit board housing.

Another embodiment of the invention is an enclosure for housing circuit boards, wherein the enclosure comprises of an interior cavity formed by top, bottom, rear, and side planar surfaces that are connected together. The enclosure further comprises of one or more enclosure partitions, and one or more configurable circuit board housings. The enclosure partitions can be used to assist in forming circuit board housings for circuit boards within the enclosure by partitioning the interior cavity in two dimensions. More specifically, at least a first positionable enclosure partition (whose length may be one of a plurality of lengths) may be used to form at least a first circuit board housing. The position of the positionable enclosure partition within the interior cavity of the enclosure determines the value of a first dimension of the circuit board housing, while the length of the positionable enclosure partition determines the maximum value and the range of values of a second dimension of the circuit board housing. The at least one enclosure partition is substantially planar, meaning that the partition is relatively flat, and two of its dimensions are much larger (at least two times larger) than its third dimension. The third dimension may only be large enough to provide a substantially small separation between two circuit boards positioned on either side of it. This separation may be approximately equal to the thickness of a typical printed circuit board, in one example embodiment. Or, the third dimension may only be large enough to provide card guides for the circuit boards positioned on either side of it, while providing a substantially small separation between the two circuit boards positioned on either side of it. The third dimension of the partition may also be sufficiently small so that it is not possible to house a circuit board within its third dimension boundaries. In other words, according to embodiments of this invention, a single positionable enclosure partition may not be a circuit board carrier, capable of mechanically supporting a circuit board by itself. In order to mechanically support a circuit board, a given positionable enclosure partition requires a second mechanically supporting structure. The second mechanically supporting structure may be a second positionable enclosure partition, or it may be the left or right interior surface of the enclosure cavity.

It can be noted that when both a first and a second positionable enclosure partition is used to form a circuit board housing within an enclosure (such as when a circuit board enclosure is formed in between enclosure partitions placed at locations 425a and 425c), the locations of both enclosure partitions determine the value of a first dimension of the circuit board housing. For example, when the first partition is placed at location 425a, and the second partition is placed at 425c, a circuit board housing is created between the two partitions that is two sub-cavities wide, while when the first partition is placed at location 425a, and the second partition is placed at 425b, a circuit board housing is created between the two partitions that is one sub-cavity wide.

It can be noted that when both a first and a second positionable enclosure partition is used to form a circuit board housing within an enclosure (such as when a circuit board enclosure is formed in between enclosure partitions placed at locations 425a and 425c), the length of both enclosure partitions determine the range of values of a second dimension of the circuit board housing. For example, when the first partition is a first length, and the second partition is a second length that is equal to twice the first length, the value of the second dimension of the circuit board housing formed between the two partitions is limited to the first length. Similarly, when the first partition is a first length, and the second partition is a second length that is equal to half the first length, the second dimension of the circuit board housing formed between the two partitions is limited to half the first length. If the lengths of the two partitions are equal in length, than the second dimension of the circuit board housing can be equal to or less than the length of the two partitions. For instance, if a first partition is length 1 (as depicted in FIG. 5A) and the second partition is length 2 (as depicted in FIG. 4B), then the range of values of the second dimension is limited to length 1. However, if both partitions are of length 2, then the range of values of the second dimension of the circuit board housing spans from the height of one sub-cavity to the height of two sub-cavities. In general, for the case wherein a circuit board housing is formed by two positionable enclosure partitions, the length of the smaller of the two partitions sets the range of values of the second dimension of the circuit board housing. For the case wherein a circuit board housing is formed by one positionable enclosure partition and one interior side of an enclosure, the length of the partition sets the range of values of the second dimension of the circuit board housing.

It can be noted from the previous discussions that for a circuit board housing formed between two positionable enclosure partitions, the two positionable enclosure partitions may be substantially the same length (other than small differences due to manufacturing tolerances), or the two positionable enclosure partitions may be substantially different in length (wherein substantially different in this context implies a difference of at least the height of one sub-cavity).

Yet another embodiment of the invention is a system comprising of an enclosure, at least one enclosure partition having a first side and a second side, and a first circuit board. The enclosure is characterized by an interior cavity of a first enclosure dimension and a second enclosure dimension. Likewise, the first circuit board is characterized by a first circuit board dimension and a second circuit board dimension. The value of the first circuit board dimension may be equal to a variety of predetermined values, substantially equal to or less than the value of first enclosure dimension. (Wherein, substantially equal to means slightly less than the value of the first enclosure dimension, so that the circuit board may fit within the enclosure interior without scraping the walls of the enclosure.) The value of the second circuit board dimension may be equal to a variety of predetermined values, substantially equal to or less than the value of the second enclosure dimension. (Wherein, substantially equal to means slightly less than the value of the second enclosure dimension, so that the circuit board may fit within the enclosure interior without scraping the walls of the enclosure.) The at least one enclosure partition is positionable within the enclosure at a variety of predetermined locations. The first circuit board may be placed on the first side of the positionable enclosure partition, wherein the partition then provides partial mechanical support for the first circuit card. In such an embodiment, the value of the first circuit board dimension of the first circuit board may determine the position of the enclosure partition within the enclosure. For instance, if the circuit board has a first dimension equal to the width of a single sub-cavity (such as circuit board 110), then the enclosure partition may be placed at either location 425a or 425c within enclosure 420 (wherein the circuit board is placed to the left of the partition if it is placed at location 425a, and wherein the circuit board is placed to the right of the partition if it is placed at location 425c). Alternatively, if the circuit board has a first dimension equal to the width of a two sub-cavities (such as circuit board 120), then the enclosure partition may only be placed at location 425b within enclosure 420.

In the enclosure of the previous embodiment, if a first circuit board with a first circuit board dimension and a second circuit board dimension is placed on a first side of the enclosure partition, and a second circuit board with a first circuit board dimension and a second circuit board dimension is placed on the second side of the enclosure partition, then the length of the enclosure partition is determined by the value of the second circuit board dimensions of both circuit boards. In particular, the length of the enclosure partition is determined by the circuit board with the larger second circuit board dimension. The value of the second circuit board dimension of the second circuit board may be equal to a variety of predetermined values substantially equal to (as previously defined) or less than the value of the second enclosure dimension. The value of the first circuit board dimension of the first circuit board, the value of the first circuit board dimension of the second circuit board, and the value of the first enclosure dimension determines if the second circuit board can be placed on the second side of the enclosure partition (opposite from the first circuit board). The value of the first circuit board dimension of the first circuit board, the value of the first circuit board dimension of the second circuit board, and the value of the first enclosure dimension also determines if a second enclosure partition is required. For instance, if the value of the first circuit board dimension of both circuit boards is equal to three sub-cavities, and the value of the first enclosure dimension is equal to four sub-cavities, then the two circuit boards cannot be placed on either side of the first enclosure partition. If the value of the first circuit board dimension of both circuit boards is equal to one sub-cavity, and the value of the first enclosure dimension is equal to four sub-cavities, then the two circuit boards can be placed on either side of the first enclosure partition, but a second enclosure partition is required on the second side of the second circuit board in order to provide mechanical support for both sides of the second circuit board.

In general, in one embodiment an enclosure that is capable of housing 2m circuit boards of a first circuit board width and a first circuit board height, organized as two rows of m circuit boards, a maximum of m−1 positionable enclosure partitions may be required in order accommodate all possible combination of circuit boards.

In a similar manner, in one embodiment, it can be shown that for an enclosure that is capable of housing 3m circuit boards of a first circuit board width and a first circuit board height, organized as three rows of m circuit boards, a maximum of 2 (m−1) positionable enclosure partitions may be required in order accommodate most possible combinations of circuit boards. (This assumes the availability of full-height, ⅓^{rd}-height and ⅔rds-height enclosure partitions.) The worst case number of positionable enclosure partitions occurs when the middle row is use to house a circuit board this is a first circuit board height and is of a circuit board length that spans the entire row, while the first and third rows comprise of circuit boards that are all a first circuit board width and a first circuit board height. In order to accommodate some configurations, for the three row enclosure, the ⅓^{rd} height positionable enclosure partitions may need to attach to the interior back of the enclosure. Alternatively, if the back-attachable ⅓^{rd} height positionable enclosure partitions were not available, some enclosure configurations may not be possible to support.

In all cases wherein a first positionable enclosure partition is used to house a circuit board operating within the enclosure, and wherein a second positionable enclosure partition is latter added to the enclosure, the operation of the circuit board is not interrupted in any manner before during or after the installation of the second positionable enclosure partition. This is insured by the fact that existing positionable enclosure partitions never have to be replaced in order to accommodate additional circuit boards. In order to accommodate all possible future configurations after the installation of the first circuit board, it must be possible to be able to install half-height positionable enclosure partitions opposite to one another.

The half-height and full-height positionable enclosure partitions additionally may contain threaded screw holes used to secure the circuit boards into the enclosure. The circuit boards may contain front panels that are able to be attached to the positionable enclosure partitions via at least one screw through the front panel of the circuit board. Additionally, for circuit boards that are installed against the left or right wall (interior side) of the enclosure, screw holes may be provided on the left and right wall of the enclosure in order to attach the front panels of the circuit boards to those walls.

Additionally, the at least one screw used to attached the front panel of a circuit board to a positionable enclosure partition (or to the side wall of the enclosure) may be permanently attached to the front panel of the circuit board.

Additionally, the at least one screw used to attached the front panel of a circuit board to a positionable enclosure partition (or to the side wall of the enclosure) may be a thumb screw.

Additionally, the at least one screw used to attached the front panel of a circuit board to a positionable enclosure partition (or to the side wall of the enclosure) may contain an Allen wrench slot.

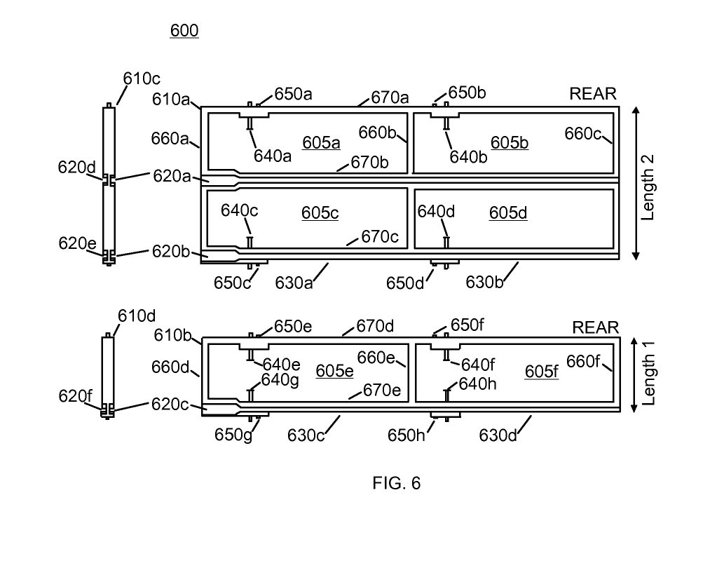

FIG. 6 shows a set of positionable enclosure partitions 600 according to another embodiment of the present invention. Shown in FIG. 6 is a side view of a full-height positionable enclosure partition 610a, a side view of a half-height positionable enclosure partition 610b, a frontal view of a full-height positionable enclosure partition 610c, and a frontal view of a half-height positionable enclosure partition 610d. Full-height (length 2) positionable enclosure partition 610a comprises of at least three vertical structures 660a-c, at least three horizontal structures 670a-c, at least two open air vents 605a-b between horizontal structures 670a and 670b, at least two open air vents 605c-d between horizontal structures 670b and 670c, at least two open air vents 630a-b beneath horizontal structure 670c, a first circuit board guide 620a on the side of partition shown, a second circuit board guide 620d on the opposite side of 620a, a third circuit board guide 620b on the side of partition shown, a fourth circuit board guide 620e on the opposite side of 620b, at least four positionable enclosure partition attachment mechanisms 640a-d in the form of screws, and at least four guide pins 650a-d. Half-height (length 1) positionable enclosure partition 610b comprises of at least three vertical structures 660d-f, at least two horizontal structures 670d-e, at least two open air vents 605e-f between horizontal structures 670d and 670e, at least two open air vents 630c-d beneath horizontal structure 670e, a first circuit board guide 620c on the side of partition shown, a second circuit board guide 620f on the opposite side of 620c, at least four positionable enclosure partition attachment mechanisms 640e-h in the form of screws, and at least four guide pins 650e-h.

In a preferred embodiment, the position of the rear attachment mechanisms 640b, 640d, 640f, 640h, are located substantially near the middle of their associated partitions (instead of near the rear of their associated partitions). (For this case, substantially near the middle implies that the attachment mechanisms 640b, 640d, 640f, 640h, are closer to the middle of the partition than to the rear of the partition.) This is done in order to enable a human hand to more easily access the rear set of attachment mechanisms 640b, 640d, 640f, 640h on each partition once the partitions are positioned within the enclosure.

Unique to the embodiments 610a and 610b is the implementation of the circuit board guides 620a-f. As shown in FIG. 6, the circuit board guides 620a-f have a larger opening at the front of the positionable enclosure partitions, and then taper down to a narrower guide. This allows for easier insertion of the circuit boards that are inserted into the guides. Also, it should be noted that each of the circuit board guides 620a, 620d are one long continuous guide from the front of the partition to the rear of the partition. It should also be noted that the lower circuit board guides 620b, 620c, 620e, 620f are not continuous guides on top and bottom, but are instead each broken into at least two segments in order to allow for passage of air flow through air vents 630a-d and over components located on the bottom side of the circuit board inserted into these slots.

The half-height enclosure partition 610b has attachment mechanisms 640e-h and guide pins 650e-h on both its top horizontal member 670d and its bottom horizontal member 670e. This allows the single half-height enclosure partition 610b to be attached to either the top interior of the enclosure cavity or the bottom interior enclosure cavity. Therefore, this particular half-height enclosure partition may be considered to be a universal half-height enclosure partition. However, there are enclosure configurations where the attachment mechanisms and or guide pins on the half-height partitions may interfere with circuitry located on circuit boards above or below the half-height partitions. This may be the case where a board that is at least two sub-cavities wide spans over under a half-height partition. In order to address these configurations, a half-height enclosure partition that is designed to be attached specifically to the bottom of the enclosure (with no attachment mechanisms or guide pins on its top horizontal member), and a half-height enclosure partition that is designed to be attached specifically to the top of the enclosure (with no attachment mechanisms or guide pins on its bottom horizontal member), may be used. Alternatively, circuit boards could be designed such that components on the circuit boards avoid the interfering attachment mechanisms and guide pins.

When full-height positionable enclosure partition 610a is mounted within the interior cavity of an enclosure, two screws 640a-b are used to attach the partition to the top interior of the enclosure, and two screws 640c-d are simultaneously used to attach the partition to the bottom interior of the enclosure. Guide pins 650a-d are used to position the partition in place prior to screwing the partition into the top and bottom interiors of the enclosure. The four screws are preferable attached to the partition, so as to prevent the dropping of screws into the enclosure.

When half-height positionable enclosure partition 610b is mounted within the interior cavity of an enclosure, the partition is attached to either the top interior of the enclosure or the bottom interior of the enclosure, not both. When the partition is attached to the top interior of the enclosure, screws 640e-d are used to attach the partition to the top interior of the enclosure, and the two screws 640g-h are not utilized. When the partition is attached to the bottom interior of the enclosure, screws 640g-h are used to attach the partition to the bottom interior of the enclosure, and the two screws 640e-f are not utilized. The four screws are preferable attached to the partition, so as to prevent the dropping of screws into the enclosure.

From the detailed views of the positionable enclosure partitions shown in FIG. 6, it is clear that the shape of the positionable enclosure partitions is substantially planar—meaning that they are flat and narrow structures. For a given partition, it is clear that the length of the partition and the dimension of the partition corresponding to the depth of the enclosure are both much larger than the dimension of the partition that lies between two circuit board housings. Such a narrow structure does not permit an enclosure partition to house a circuit board within its narrow confines; it may instead only provide a slight separation between two or more circuit boards residing external to it. Therefore, referring to the positionable enclosure partitions as substantially planar is justified. Another way to describe the shape of the enclosure partitions is to describe the structures as substantially two-dimensional; meaning that two of dimensions dominate the third dimension in stature.

A system for housing circuit boards supporting up to eight sub-cavities has been described in great detail. This system contained two rows of sub-cavities, with up to four sub-cavities in each row. Also, a system for housing circuit boards with three rows of sub-cavities has been described, but in less detail. It should be noted that embodiments of the invention are not limited to any number of rows, nor is it limited to any number of sub-cavities in each row. In general, a system for housing circuit boards as described herein may comprise of a an interior cavity that may be partitioned into an array of sub-cavities. The array of sub-cavities may further be comprised of n rows and m columns. A positionable enclosure partition may be placed between any of the m columns of sub-cavities. A minimum of m−1 m−1 positionable enclosure partitions may be placed in a system comprising of n rows and m columns. Each of the m−1 positionable enclosure partitions may have a height (i.e., length) equal to that of the height of n rows. Alternatively, each positionable enclosure partition may have a height (i.e., length) equal to the height of one to n rows.

Although the embodiments of the invention described previously utilized positionable enclosure partitions that were mounted vertically, embodiments of the invention are not limited to positionable enclosure partitions that are mounted vertically. Embodiments of the invention include a system for housing circuit boards wherein the positionable enclosure partitions are mounted horizontally instead of vertically. Such partitions would be used to separate rows of sub-cavities instead of columns of sub-cavities. These partitions could be attached to the left and right interior walls of the enclosure.

More complex, but not precluded by this invention, is a system for housing circuit boards comprising of both vertical and horizontal positionable enclosure partitions.

If an enclosure for housing circuit boards 420 initially comprises of no positionable enclosure partitions, then when a full-height positionable enclosure partition is placed in the interior cavity of the enclosure at the position indicated by the vertical dashed line 425a, then a first size circuit board housing is formed to the left of the positionable enclosure partition. This thus formed circuit board housing may house circuit boards 110 of a first circuit board width and a first circuit board height. Alternatively, this thus formed circuit board housing may house a circuit board 140 of a first circuit board width and a second circuit board height. If this same positionable enclosure partition is instead placed in the interior cavity of the enclosure at the position indicated by the vertical dashed line 425b, then a second size circuit board housing is formed to the left of the positionable enclosure partition. This thus formed circuit board housing may house circuit boards 120 of a second circuit board width and a first circuit board height. Alternatively, this thus formed circuit board housing may house a circuit board 150 of a second circuit board width and a second circuit board height.

From the previous example, it can be observed that, in general, the system so described for housing circuit boards comprising of an enclosure with an interior cavity, and at least one positionable enclosure partition, exhibits the following behavior. When the at least one positionable enclosure partition is placed in a first position within the interior cavity at least a first size circuit board housing is formed, enabling the housing of at least a first circuit board of a first circuit board size (110, for example), and wherein when the at least first positionable enclosure partition is placed in a second position within the interior cavity at least a second size circuit board housing is formed, enabling the housing of at least a second circuit board of a second circuit board size (120, for example), wherein the second circuit board size (120, for example) is substantially different from the first circuit board size (110, for example). (In this context, substantially different in size means that the difference between the two circuit boards is at least equal to the difference in size between one sub-cavity and two sub-cavities.) It can further be observed, that when the at least one positionable enclosure partition is placed in a first position, the enclosure in unable to house the circuit board of the second size, and similarly, when the at least one positionable enclosure partition is placed in a second position, the enclosure in unable to house the circuit board of the first size. In general, any size enclosure constructed according to the principles so described by the embodiments of this invention will exhibit the above so described behavior.

It can be further observed that the positionable enclosure partitions so described by this invention are substantially two-dimensional—meaning two of its dimensions are substantially larger than the third dimension.

Returning to the previous example embodiment, if an enclosure for housing circuit boards 420 initially comprises of no positionable enclosure partitions, then when a full-height positionable enclosure partition is placed in the interior cavity of the enclosure at the position indicated by the vertical dashed line 425a, then a first size circuit board housing is formed to the left of the positionable enclosure partition, and a second size circuit board housing is formed to the right of the positionable enclosure partition. The thus formed first size circuit board housing may house circuit boards 110 of a first circuit board width and a first circuit board height, or alternatively, the thus formed first size circuit board housing may house a circuit board 140 of a first circuit board width and a second circuit board height. The thus formed second circuit board housing may house circuit boards 125 of a third circuit board width and a first circuit board height, or alternatively, the thus formed second size circuit board housing may house a circuit board of a third circuit board width and a second circuit board height. If this same positionable enclosure partition is instead placed in the interior cavity of the enclosure at the position indicated by the vertical dashed line 425b, then a third size circuit board housing is formed to the left of the positionable enclosure partition. This thus formed circuit board housing may house circuit boards 120 of a second circuit board width and a first circuit board height. Alternatively, this thus formed circuit board housing may house a circuit board 150 of a second circuit board width and a second circuit board height. A circuit board housing is formed to the right of the enclosure positioned at location 425b that is also a third size circuit board housing, capable of housing either a circuit board 120 of a second circuit board width and a first circuit board height or a circuit board 150 of a second circuit board width and a second circuit board height.

Returning to the previous example embodiment, if an enclosure for housing circuit boards 420 initially comprises of no positionable enclosure partitions, then the enclosure may house circuit boards 130 of a fourth size width. When a half-height positionable enclosure partition is placed in the interior cavity of the enclosure at the position indicated by the vertical dashed line 425a, then a second size circuit board housing is formed to the left of the positionable enclosure partition, and a third size circuit board housing is formed to the right of the positionable enclosure partition, Now, in addition to being able to still house a circuit board 130 of a fourth circuit board width, the system is able to house a circuit board 110 of a first circuit board width and a first circuit board height, and a circuit board 125 of a third circuit board width and a first circuit board height.

In another embodiment of the invention, a system for housing circuit boards comprises of an enclosure with an interior cavity, and a positionable enclosure partition, wherein the enclosure allows for the placement of the positionable enclosure partition at only a single location within the interior cavity of the enclosure. An example of such an enclosure is one that is only as wide as the width of a circuit board (120) of a second circuit board width, and is only as tall as the height of a circuit board 150 of a second circuit board height. If the enclosure for housing circuit boards initially comprises of no positionable enclosure partitions, then the interior of the enclosure forms a circuit board housing that may house either a circuit board 120 of a second circuit board width and a first circuit board height or a circuit board 150 of a second circuit board width and a second circuit board height. If a full-height positionable enclosure partition is placed within the center of the enclosure, a circuit board housing is formed to the left and to the right of the partition. Each circuit board housing is able to house a circuit board of a first circuit board width and a first circuit board height, or each circuit board housing is able to house a circuit board of a first circuit board width and a second circuit board height. Once the single partition is placed within the enclosure, the enclosure is no longer able to house a circuit board of a second circuit board width.

Embodiments of the invention so described further comprise of positionable enclosure partitions of different lengths. The first dimension of all positionable enclosure partitions is equal to the enclosure depth. The second dimension of the positionable enclosure partition is equal to an integer number of first circuit board heights, and is referred to as the length of the positionable enclosure partition.

As described, the system for housing circuit boards comprises of a plurality of predetermined positions within the enclosure where positionable enclosure partitions may be placed. The partitions are used to create circuit board housings (out of sub-cavities) within the interior cavity of the enclosure. Each sub-cavity may have associated with it a sub-section of a backplane located in the rear interior of the enclosure cavity. Each backplane sub-section may have at least one backplane connector within its boundaries. The number of backplane connectors within each sub-section of the backplane is the same in the preferred embodiment. The size and type of connectors within each sub-section of the backplane is the same in the preferred embodiment. This allows all sub-cavities to be treated as identical entities, thus allowing for the insertion of a particular circuit board into any of the sub-cavities or group of sub-cavities (circuit board housings).

Embodiments of the invention further include a method of configuring an enclosure comprising of placing positionable enclosure partitions within the enclosure such that circuit boards that differ in at least two dimensions may be housed within the enclosure.

What is claimed is:

1. A system for housing circuit boards, comprising:
an enclosure with an interior cavity;
at least one substantially planar positionable enclosure partition; and
at least one circuit board housing with at least a first dimension, located within the interior cavity of the enclosure and formed in part by the positionable enclosure partition;
wherein the position within the enclosure of the enclosure partition determines the value of the at least first dimension of the at least one circuit board housing.

2. The system of claim 1, wherein the length of the at least one substantially planar positionable enclosure partition determines the range of values of a second dimension of the at least one circuit board housing within the enclosure.

3. The system of claim 1, wherein the system contains a plurality of substantially planar positionable enclosure partitions, wherein the enclosure partitions may be of a variety of lengths.

4. The system of claim 1, wherein the at least one substantially planar positionable enclosure partition provides mechanical support for circuit boards on both sides of its substantially planar structure.

5. The system of claim 1, wherein the system provides a means for attaching the at least one substantially planar positionable enclosure partition to the enclosure.

6. The system of claim 1, wherein the system provides a means for guiding the at least one substantially planar positionable enclosure partition into a predefined location within the enclosure.

7. The system of claim 1, wherein the system provides a means for securing a circuit board to the at least one substantially planar positionable enclosure partition.

8. The system of claim 1, wherein the enclosure contains a plurality of predetermined locations for the at least one substantially planar positionable enclosure partition.

9. The system of claim 1, wherein the interior cavity may be segmented into an array of sub-cavities comprised of n rows and m columns, and wherein the at least one enclosure partition may be positioned between any two columns of the array.

10. The system of claim 9, wherein placement of the at least one enclosure partition results in the formation of a first and second set of n circuit board housings, each having at least a first dimension, wherein the first set of n circuit board housings have first dimension whose value is substantially equal to the width of i columns, and wherein the second set of n circuit board housings have a first dimension whose value is substantially equal to the width of m−i columns, wherein i is any integer in the range of 1 to m−1.

11. A method of housing circuit boards within an enclosure comprising:
creating at least one circuit board housing within the enclosure utilizing at least one positionable enclosure partition;
wherein the length of the at least one positionable enclosure partition is chosen so as to accommodate a predetermined range of values for a first dimension of the at least one circuit board housing.

12. The method of claim 11, further comprising of placing the at least one positionable enclosure partition within the enclosure at one of a plurality of predetermined locations so as to define a value for a second dimension of the circuit board housing.

13. An enclosure for housing circuit boards, comprising:
an interior cavity formed by top, bottom, rear, and side interior and exterior surfaces;
at least a first positionable enclosure partition, the length of which may be one of a plurality of lengths; and
at least a first configurable circuit board housing, formed within the interior cavity and having at least a first dimension;
wherein the position within the cavity of the positionable enclosure partition determines the value of the at least first dimension of the at least first configurable circuit board housing.

14. The enclosure of claim 13, wherein the at least first configurable circuit board housing further includes a second dimension, wherein the length of the at least first positionable enclosure partition determines the maximum value of the second dimension of the at least first configurable circuit board housing.

15. The enclosure of claim 13, further comprising:
at least a second positionable enclosure partition; and
at least a second configurable circuit board housing having at least a first dimension;
wherein the position within the cavity of the at least first and the at least second positionable enclosure partitions determines the value of the at least first dimension of the at least second configurable circuit board housing.

16. The enclosure of claim 13, further comprising:
at least a second positionable enclosure partition, the length of which may be one of a plurality of lengths; and
at least a second configurable circuit board housing having at least a first dimension and at least a second dimension;
wherein the lengths of the at least first and of the at least second positionable enclosure partitions determine the range of values for the at least second dimension of the at least second circuit board housing.

17. The enclosure of claim 13, further comprising of at least a second positionable enclosure partition, wherein the length of the at least second positionable enclosure partition may be substantially different than the length of the at least first positionable enclosure partition.

18. The enclosure of claim 13, further comprising of at least a second positionable enclosure partition, wherein the length of the at least second positionable enclosure partition may be substantially the same as the length of the at least first positionable enclosure partition.

19. A system, comprising:
an enclosure with an interior cavity;
at least one substantially planar enclosure partition, positionable within the interior of the enclosure, and having a first side and a second side; and
at least a first circuit board, placed on the first side of the at least one enclosure partition, the first circuit board having a first circuit board dimension and a second circuit board dimension;
wherein the value of the first circuit board dimension determines the position of the at least one enclosure partition.

20. The system of claim 19, further comprising of at least a second circuit board, placed on the second side of the at least one enclosure partition, the second circuit board having a first circuit board dimension and a second circuit board dimension, wherein the length of the at least one enclosure partition is determined by the value of the second circuit board dimension of the at least first circuit board and by the value of the second circuit board dimension of the at least second circuit board.

21. The system of claim 19, wherein the at least one positionable enclosure partition provides partial mechanical support for the at least first circuit board.
